(19) United States
(12) Patent Application Publication
(10) Pub. No.: US 2012/0084620 A1
(43) Pub. Date: Apr. 5, 2012

(54) TRANSMISSION DEVICE AND RECEIVING DEVICE

(75) Inventor: Shunji MIYAZAKI, Kawasaki (JP)

(73) Assignee: FUJITSU LIMITED, Kawasaki-shi (JP)

(21) Appl. No.: 13/323,383

(22) Filed: Dec. 12, 2011

Related U.S. Application Data
(63) Continuation of application No. PCT/JP2009/061126, filed on Jun. 18, 2009.

(51) Int. Cl. H03M 13/05; G06F 11/10; H03M 13/09

(52) U.S. Cl. 714/752; 714/800; 714/E11.032

(57) ABSTRACT

A transmission device according to the present invention splits information bits, calculates two parity bit sequences from the split information bits, combines the parity bit sequences with information bits (encoded information bit) such that the calculated two parity bit sequences are not added to the same information bits. Then, the transmission device changes the order of the combined information, distributes each of the reordered information to levels L0 and L1, and performs multi level modulation, thus making the reliability of each bit constant.

### CROSS-REFERENCE TO RELATED APPLICATION

This application is a continuation of International Application No. PCT/JP2009/061126, filed on Jun. 18, 2009, now pending, the entire contents of which are herein wholly incorporated by reference.

### FIELD

The embodiments discussed herein are directed to a transmission device that encodes and modulates information bits.

### BACKGROUND

In recent years, transmitters transmit information bits to receivers via radio channels after encoding and modulating the information bits. Turbo coding is used as an encoding method for encoding information bits. Furthermore, multi level modulation and hierarchical modulation are used as methods for modulating information bits. In the following, turbo coding, multi level modulation, and hierarchical modulation will be described.

Turbo coding is an encoding method using, in combination, element codes and interleavers. Here, the turbo coding standardized by the 3rd Generation Partnership Project (3GPP) will be described as an example of turbo coding. FIG. 12 is a schematic diagram illustrating an example of a conventional turbo encoder.

As illustrated in FIG. 12, a turbo encoder 10 includes element encoders 20 and 30 and an interleaver 40. The element encoder 20 includes delay devices 21 to 23, whereas the element encoder 30 includes delay devices 31 to 33. By inputting information bits to the element encoder 20 without processing them, feedback-type convolutional encoding is performed, thereby creating a parity bit sequence 1.

In contrast, for information bits that are input to the element encoder 30, the interleaver 40 changes the sequence of the bit string. By inputting, to the element encoder 20, information bits in which the sequence of the bit string is changed, feedback-type convolutional encoding is performed, thereby creating a parity bit sequence 2.

Then, the turbo encoder 10 outputs a bit string obtained by combining, in a serial manner, a systematic bit sequence associated with the information bits, the parity bit sequence 1, and the parity bit sequence 2.

Subsequently, a process for decoding the information bits that are encoded by the turbo encoder 10 will be described. FIG. 13 is a schematic diagram illustrating an example of a conventional turbo decoder. As illustrated in FIG. 13, a turbo decoder 50 includes element decoders 60 and 70, an interleaver 80, and a deinterleaver 90.

The turbo decoder 50 decodes the encoded information bits in accordance with likelihood data yₛ, yₚ₁, and yₚ₂. The likelihood data yₛ is an encoded sequence in which noise is added to the systematic bit sequence during the transmission, the likelihood data yₚ₁ is an encoded sequence in which noise is added to the parity bit sequence 1 during the transmission, and the likelihood data yₚ₂ is an encoded sequence in which noise is added to the parity bit sequence 1 during the transmission.

The interleaver 80 changes the sequence of information bits in a similar manner as to the interleaver 40 illustrated in FIG. 12. The deinterleaver 90 changes back the sequence of information bits changed by the interleaver 80.

The element decoders 60 and 70 are decoders that obtain a posteriori probability by using, for example, the maximum a posteriori probability (MAP) decoding or a soft output decoding algorithm of the soft output Viterbi algorithm (SOVA).

By using a redundant bit of the likelihood data yₚ₁ and the posteriori probability obtained by the element decoder 70, the element decoder 60 repeatedly performs error correction decoding on the likelihood data yₛ to obtain a posteriori probability. The element decoder 60 outputs the obtained posteriori probability to the element decoder 70 via the interleaver 80.

By using a redundant bit of the likelihood data yₚ₂ and the posteriori probability obtained by the element decoder 60, the element decoder 70 repeatedly performs error correction decoding on the likelihood data yₛ to obtain a posteriori probability. The element decoder 70 outputs the obtained posteriori probability to the element decoder 60 via the deinterleaver 90. Furthermore, the posteriori probability obtained by the element decoder 70 becomes decoded information bits. In the turbo decoding, error correction performance is enhanced because the element decoders 60 and 70 repeatedly perform error correction decoding.

In signal modulation, information bits are transmitted by modulating the phase or amplitude of a reference signal (baseband). For example, a quadrature phase shift keying (QPSK) scheme is a modulation technique for fixing the amplitude and allocating 2-bit information to four phases. FIG. 14 is a schematic diagram illustrating the QPSK scheme. In FIG. 14, the vertical axis indicates imaginary numbers and the lateral axis indicates real numbers. The bit patterns (00, 10, 11, 01) are denoted by a symbol represented by a specific phase. There are four symbols in a QPSK scheme. In the QPSK scheme in which amplitudes are fixed, the reliability of 2 bits (a first bit and a second bit) are the same.

In contrast, multi level modulation is a modulation technique for transmitting a larger amount of information than the amount transmitted by using the QPSK scheme and is performed by allocating, to each binary bit, a combination of a different amplitude and a different phase. FIG. 15 is a schematic diagram illustrating 16 QAM, which is one of the multi level modulation techniques. In FIG. 15, the vertical axis indicates imaginary numbers and the lateral axis indicates real numbers. As illustrated in FIG. 15, in 16-QAM, each 4-bit information is allocated to each combination of four amplitudes and four phases. The 16-QAM contains 16 symbols. In 16-QAM, the reliabilities of four bits (a first bit, a second bit, a third bit, and a fourth bit) are not the same but vary. Specifically, the reliability of the first bit is different from that of the third bit and the reliability of the second bit is different from that of the fourth bit.

The grayscale modulation technique is a technique, used in multi level modulation, for allocating information bits allocated to a single symbol to different users. For example, from among four bits allocated to a single symbol, a first bit is allocated to a user A, a second bit is allocated to a user B, a third bit is allocated to a user C, and a fourth bit is allocated to a user D.

FIG. 16 is a schematic diagram illustrating the grayscale modulation technique. As illustrated in FIG. 16, in the grayscale modulation technique, a bandwidth B is divided into a plurality of resource blocks (RB) and a symbol is allocated to some of the resource blocks. Then, a single bit in an information bit associated with a symbol is used as a bit allocated to a corresponding user. For example, in FIG. 16, if RB0 and RB1 are allocated to the user A, from among bit sequences of symbols of RB0 and RB1, a first bit is allocated to the user A. FIG. 17 is a schematic diagram illustrating the fading of a radio wave transmitted to the user A and a radio wave transmitted to the user B.

More flexible scheduling is performed by allocating a single symbol to a plurality of users rather than allocating information bits allocated to a single symbol to a single user in this way. Furthermore, by allocating information bits contained in a symbol to each user, as illustrated in FIG. 17, the effect of variable reliability can be averaged per user, thus enhancing the overall throughput.

Bit interleaved coded modulation (BICM) and the multi level coding (MLC) are used as a combination of the transmission method and the modulation technique described above.

FIG. 18 is a schematic diagram illustrating the configuration of a BICM-type transmitter. As illustrated in FIG. 18, in a similar manner to the turbo encoder, a transmitter 100 includes an encoding unit 101 that encodes information bits. Furthermore, the transmitter 100 includes a channel interleaver 102 that changes the sequence of encoded information bits and a modulating unit 103 that performs the multi level modulation or the hierarchical modulation.

In contrast, an MLC-type transmitter divides information bits, encodes each of the divided information bits, and performs multi level modulation. FIG. 19 is a schematic diagram illustrating the configuration of an MLC-type transmitter. As illustrated in FIG. 19, a transmitter 110 includes a splitting unit 111, encoding units 112a and 112b, channel interleavers 113a and 113b, and a multi level modulating unit 114.

The splitting unit 111 is a processing unit that divides information bits into two, outputs a first divided information bits to the encoding unit 112a, and outputs a second information bits to the encoding unit 112b.

The encoding unit 112a encodes information bits and outputs the encoded information bits to the channel interleaver 113a. The encoding unit 112b encodes the information bits and outputs the encoded information bits to the channel interleaver 113b.

The channel interleaver 113a changes the sequence of the encoded information bits and outputs the reordered information bits to the multi level modulating unit 114. The channel interleaver 113b changes the sequence of the encoded information bits and outputs the reordered information bits to the multi level modulating unit 114.

As illustrated in FIG. 15, when allocating a symbol for four bits, the multi level modulating unit 114 allocates information bits acquired from the channel interleaver 113a to a first bit and a second bit (L0) and allocates an information bit acquired from the channel interleaver 113b to a third bit and a fourth bit (L1). Then, the information bits are transmitted by modulating a signal having an amplitude and a phase in accordance with the allocated symbol.

In the MLC-type transmitter, the specifying of the overall error rate is improved by adjusting, by the encoding units 112a and 112b, the encoding rate of information bits allocated to each of the levels L0 and L1 and by taking into consideration the information bits allocated to each of the levels L0 and L1. The multi stage decoding (MSD) is known as a method for decoding information bits encoded using the MLC method.

Patent Document 1: Japanese Laid-open Patent Publication No. 200-344548

Non-patent Document 1: “3GPP TS 36.212” v 8.5.0 (2008-12)

Non-patent Document 2: U. Wachsmann, J. Huber, “Power and bandwidth efficient digital communication using turbo codes in multilevel codes”, European Transactions on Telecommunications Vol. 6, No. 5, pp 557-567

However, in the transmission method that uses, in combination, turbo codes and multi level modulation, because the reliability of bits allocated to a symbol varies, the reliability of each bit contained in the information bits is not constant; therefore, there is a problem in that information bits having various reliabilities are input to a decoder. When comparing a case of decoding information bits having uneven reliability with a case of decoding information bits having constant reliability, the efficiency of the decoding is low when decoding the information bits having uneven reliability.

In the MLC method, it is possible to make the reliability constant; however, a code needs to be divided into two or more even though the code length is short. Because the turbo coding has a characteristic in which the property of the code is degraded if the code length is short, there is a problem in that, in the MLC method, the property of the code is degraded as the code length becomes shorter. Furthermore, in the MLC method, the reliability of part of the likelihood data is easily affected by degradation due to fading.

### SUMMARY

According to an aspect of an embodiment of the invention, a transmission device includes a first element encoder that encodes information bits and creates a first parity bit sequence; a second element encoder that encodes information bits in which a sequence of bit strings are changed and creates a second parity bit sequence; a first rate matching unit that creates information obtained by combining a part of the information bits with the first parity bit sequence and adjusts a bit size of the created information; a second rate matching unit that creates information obtained by combining a part of the information bits with the second parity bit sequence and adjusts a bit size of the created information; and a multi level modulating unit that creates a bit string by combining the information that is output from the first rate matching unit with the information that is output from the second rate matching unit and performs multi level modulation in accordance with the bit string.

The object and advantages of the embodiment will be realized and attained by means of the elements and combinations particularly pointed out in the claims.

It is to be understood that both the foregoing general description and the following detailed description are exemplary and explanatory and are not restrictive of the embodiment, as claimed.

### BRIEF DESCRIPTION OF DRAWINGS

FIG. 1 is a schematic diagram illustrating the configuration of a transmission device according to a first embodiment;

FIG. 2 is a schematic diagram illustrating the structure of information that is output by a P/S converting unit 124a;

FIG. 3 is a schematic diagram illustrating the structure of information that is output by a P/S converting unit 124b;

FIG. 4 is a schematic diagram illustrating the structure of information to which a repetition is added;

FIG. 5 is a schematic diagram illustrating the structure of information obtained by performing puncturing;

FIG. 6 is a schematic diagram illustrating the configuration of a receiving device according to the first embodiment;

FIG. 7 is a flowchart illustrating the flow of a process performed by the transmission device according to the first embodiment;

FIG. 8 is a schematic diagram illustrating the configuration of a transmission device according to a second embodiment; FIG. 9 is a schematic diagram illustrating the structure of information that is output by an encoding unit;

FIG. 10 is a schematic diagram illustrating the configuration of a receiving device according to the second embodiment;

FIG. 11 is a schematic diagram illustrating another process performed by a multi level modulating unit;

FIG. 12 is a schematic diagram illustrating an example of a conventional turbo encoder;

FIG. 13 is a schematic diagram illustrating an example of a conventional turbo decoder;

FIG. 14 is a schematic diagram illustrating a QPSK technique;

FIG. 15 is a schematic diagram illustrating 16 QAM, which is an example used in a multi level modulation technique;

FIG. 16 is a schematic diagram illustrating a grayscale modulation technique;

FIG. 17 is a schematic diagram illustrating fading of a radio wave transmitted to a user A and a radio wave transmitted to a user B;

FIG. 18 is a schematic diagram illustrating the configuration of a BICM-type transmitter; and

FIG. 19 is a schematic diagram illustrating the configuration of an MLC-type transmitter.

### DESCRIPTION OF EMBODIMENTS

Preferred embodiments of the present invention will be explained with reference to accompanying drawings.

### [a] First Embodiment

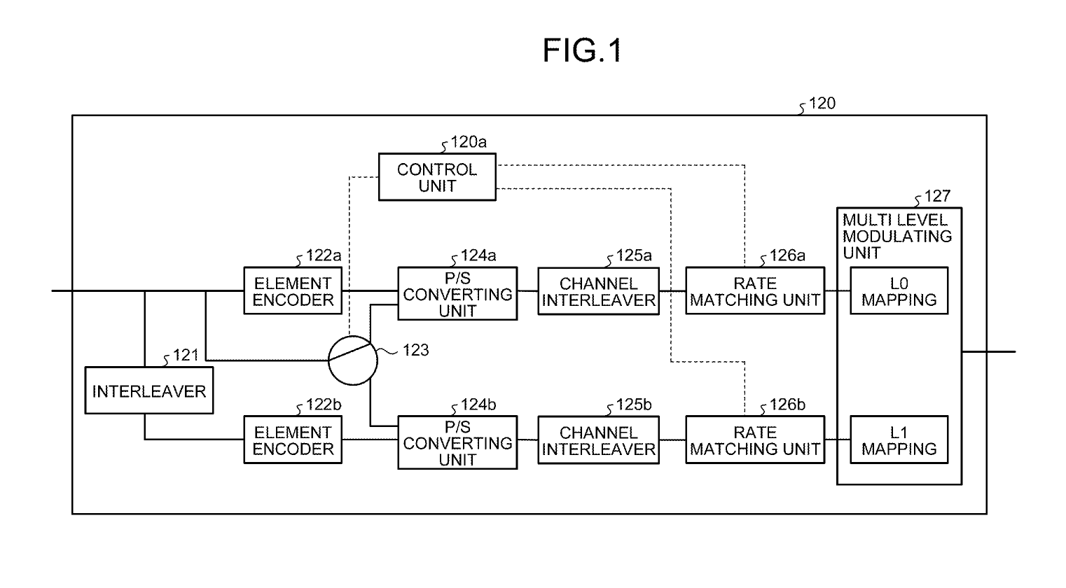

The configuration of a transmission device according to a first embodiment will be described. FIG. 1 is a schematic diagram illustrating the configuration of a transmission device according to a first embodiment. As illustrated in FIG. 1, a transmission device 120 includes a control unit 120a, an interleaver 121, element encoders 122a and 122b, a distribution switch 123, P/S converting units 124a and 124b, channel interleavers 125a and 125b, rate matching units 126a and 126b, and a multi level modulating unit 127.

In accordance with the size K of information bits, the number of code bits N associated with the number of encoded information bits, and the encoding rate RO of the rate matching unit 126a, the control unit 120a calculates the sizes K0 and K1 of the information bits distributed by the distribution switch and the encoding rate R1 of the rate matching unit 126b. It is assumed that the size K of the information bits, the number of code bits N, and the encoding rate R0 are previously stored in the control unit 120a.

The control unit 120a calculates the size K0 of the information bits using Equation (1) below:

K0=N=R0/2 (1)

The control unit 120a calculates the size K1 of the information bits using Equation (2) below:

K1=K−K0 (2)

The control unit 120a calculates the encoding rate R1 of the rate matching unit 126b using Equation (3) below:

R1=2×(K−K0)/N=2×R−R0 (3)

The control unit 120a outputs the sizes K0 and K1 of the information bits to the distribution switch 123. Furthermore, the control unit 120a outputs the encoding rate R0 to the rate matching unit 126a and outputs the encoding rate R1 to the rate matching unit 126b.

The interleaver 121 is a processing unit that changes the sequence of information bits when acquiring the information bits. The interleaver 121 outputs the reordered information bits to the element encoder 122b.

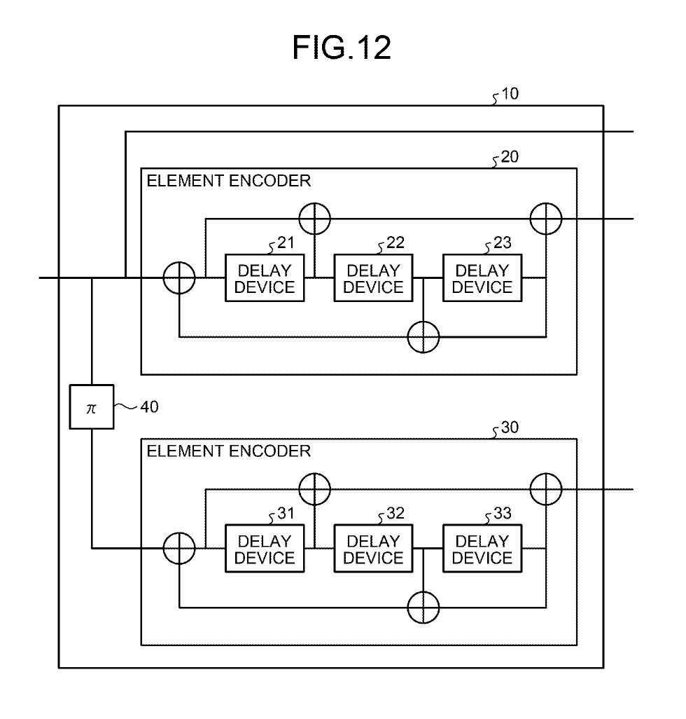

When acquiring the information bit, the element encoder 122a performs feedback-type convolutional encoding and outputs a parity bit sequence 1 in a similar manner to the element encoder 20 illustrated in FIG. 12.

When acquiring reordered information bits performed by the interleaver 121, the element encoder 122b performs feedback-type convolutional encoding and outputs a parity bit sequence 2 in a similar manner to the element encoder 30 illustrated in FIG. 12.

The distribution switch 123 acquires the sizes K0 and K1 of the information bits from the control unit 120a and outputs, from among all of the sizes of the information bits externally acquired, the information bits whose size is K0 to the P/S converting unit 124a and the information bits whose size is K1 to the P/S converting unit 124b.

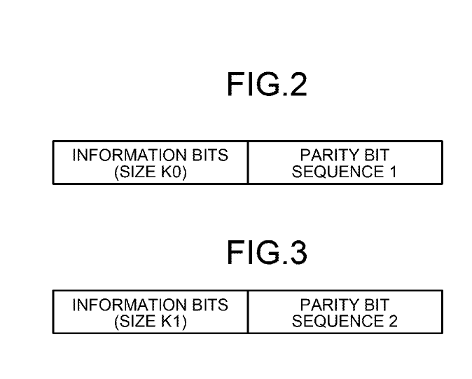

The P/S converting unit 124a is a processing unit that combines the parity bit sequence 1 acquired from the element encoder 122a with the information bits having the size K0 acquired from the distribution switch 123 and outputs the combined information to the channel interleaver 125a. FIG. 2 is a schematic diagram illustrating the structure of information that is output by the P/S converting unit 124a.

The P/S converting unit 124b is a processing unit that combines the parity bit sequence 2 acquired from the element encoder 122b with the information bits having the size K1 acquired from the distribution switch 123 and outputs the combined information to the channel interleaver 125b. FIG. 3 is a schematic diagram illustrating the structure of information that is output by the P/S converting unit 124b.

When acquiring the information in which the information bits are combined with the parity bit sequence 1, the channel interleaver 125a, which is a processing unit, divides the acquired information into a plurality of data units and reorders the data units in accordance with a predetermined rule. The channel interleaver 125a outputs the reordered information to the rate matching unit 126a.

When acquiring the information obtained by combining the information bits with the parity bit sequence 2, the channel interleaver 125b, which is a processing unit, divides the acquired information into a plurality of data units and reorders the data units in accordance with a predetermined rule. The channel interleaver 125b outputs the reordered information to the rate matching unit 126a.

The rate matching unit 126a is a processing unit that calculates the bit size of a physical channel in accordance with the encoding rate R0 and adjusts the size of the information acquired from the channel interleaver 125a such that the size of the information is associated with the calculated bit size. The bit size of the physical channel becomes K0+K. The size K0 of the information bits is calculated using Equation (1) above.

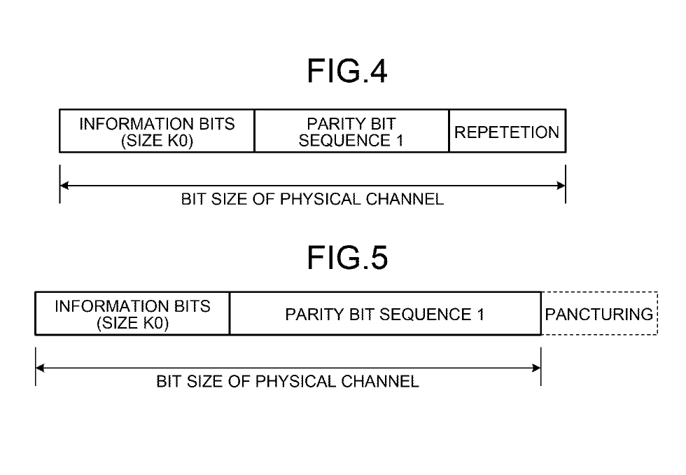

If the bit size of the information acquired from the channel interleaver 125a is smaller than that of the physical channel, the rate matching unit 126a adds a repetition to the information in order to match the bit sizes. FIG. 4 is a schematic diagram illustrating the structure of information to which a repetition is added.

In contrast, if the bit size of the information acquired from the channel interleaver 125a is larger than that of the physical channel, the rate matching unit 126a performs the puncturing, in which part of the information is deleted, in order to match the bit sizes. FIG. 5 is a schematic diagram illustrating the structure of information obtained by performing puncturing. The rate matching unit 126a outputs the information, whose size is adjusted, to the multi level modulating unit 127.

The rate matching unit 126b is a processing unit that calculates the bit size of a physical channel in accordance with the encoding rate R1 and adjusts the size of the information acquired from the channel interleaver 125b such that the size of the information is associated with the calculated bit size. The bit size of the physical channel becomes K1+K. The size K0 of the information bits is calculated using, for example, Equation (4) below:

K0=N×R1/2 (4)

The rate matching unit 126b outputs the information, whose size is adjusted, to the multi level modulating unit 127.

The multi level modulating unit 127 is a processing unit that sequentially extracts, from the information acquired from the rate matching units 126a and 126b, a total of 4 bits, i.e., 2 bits per information, maps a symbol associated with the extracted 4 bits, and transmits the information bits.

The multi level modulating unit 127 associates the 2-bit information extracted from the information acquired from the rate matching unit 126a with a first bit and a second bits (L0) of 4 bits constituting the symbol. Furthermore, the multi level modulating unit 127 associates the 2-bit information extracted from the information acquired from the rate matching unit 126b with a third bit and a fourth bit (L1) of 4 bits constituting the symbol.

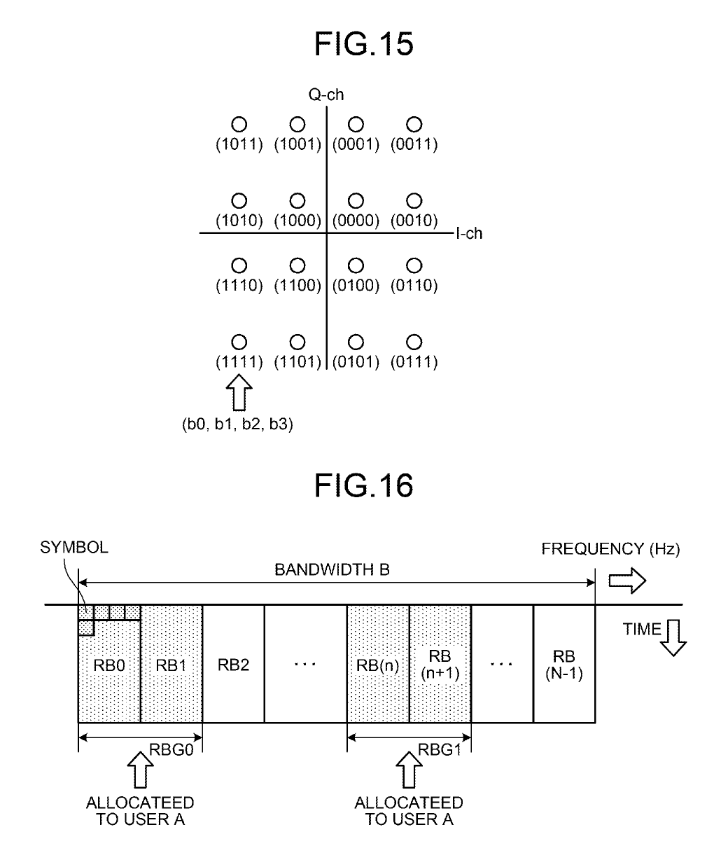

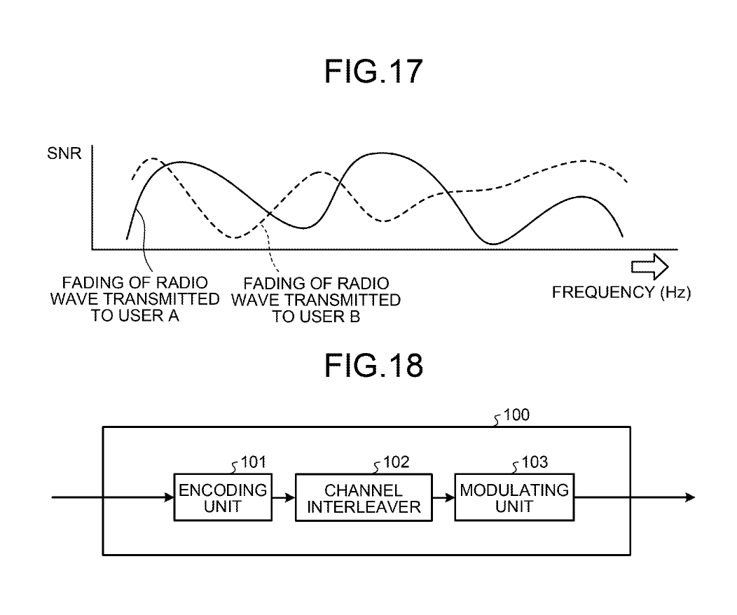

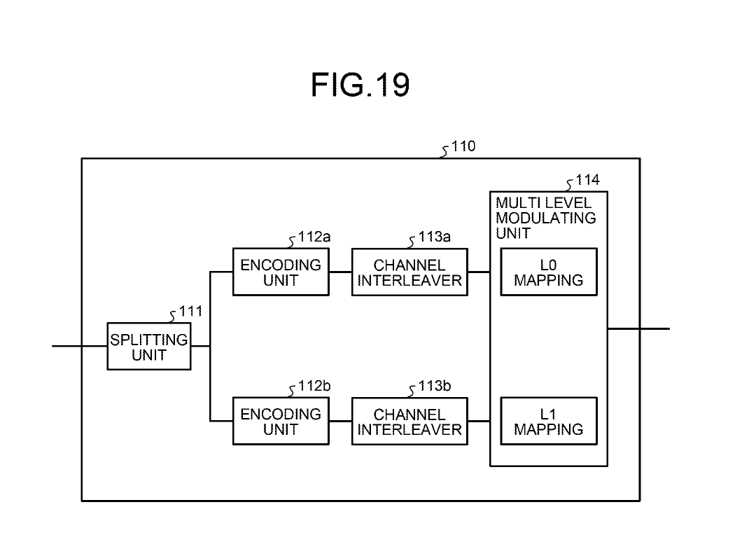

For example, if the 2-bit information extracted from the information acquired from the rate matching unit 126a is “01” and if the 2-bit information extracted from the information acquired from the rate matching unit 126b is “10”, the multi level modulating unit 127 maps the symbol in a fourth quadrant in FIG. 15.

As described above, the transmission device 120 divides information bits, calculates the parity bit sequences 1 and 2 from the divided information bits, and combines the parity bit sequences 1 and 2 with the information bits (encoded information bits) in such a manner that the calculated parity bit sequences 1 and 2 are not added to the same information bits. Then, the transmission device 120 reorders the combined information, distributes the reordered information to each of the levels L0 and L1, and performs the multi level modulation. Accordingly, the transmission device 120 equally exerts an effect of noise occurring at the transmission on each bit contained in the information bits, thus making the reliability of each bit contained in the information bits constant.

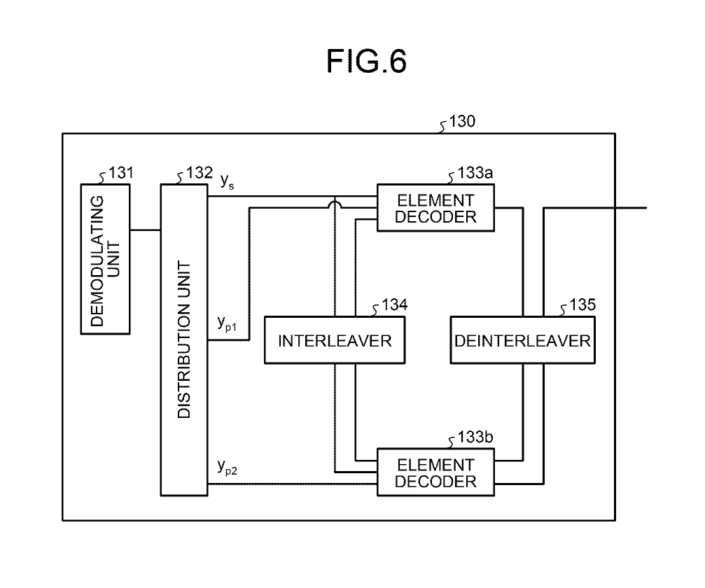

In the following, the configuration of a receiving device according to the first embodiment will be described. FIG. 6 is a schematic diagram illustrating the configuration of a receiving device 130 according to the first embodiment. As illustrated in FIG. 6, the receiving device 130 includes a demodulating unit 131, a distribution unit 132, element decoders 133a and 133b, an interleaver 134, and a deinterleaver 135.

The demodulating unit 131 is a processing unit that acquires modulated information from the transmission device 120 and demodulates the acquired information. The demodulating unit 131 outputs the demodulated information to the distribution unit 132.

When acquiring the information from the demodulating unit 131, the distribution unit 132 extracts likelihood data yₛ, Yₚ₁, and yₚ₂ from the acquired information. Then, the distribution unit 132 outputs the likelihood data yₛ to the element decoder 133a and the interleaver 134 and outputs the likelihood data yₚ₁ to the element decoder 133a. Furthermore, the distribution unit 132 outputs the likelihood data yₚ₂ to the element decoder 133b.

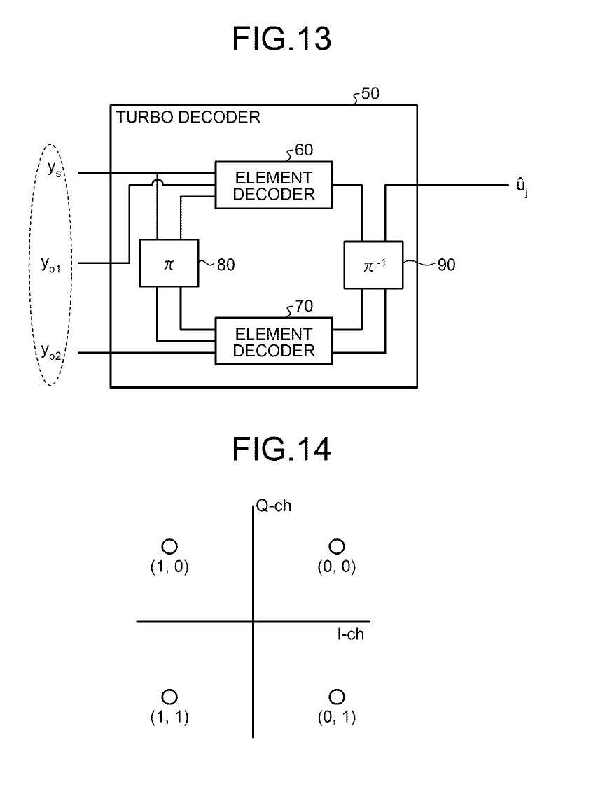

In a similar manner to the element decoders 60 and 70 illustrated in FIG. 13, the element decoders 133a and 133b obtain a posteriori probability using, for example, the MAP decoding or a soft output decoding algorithm of SOYA.

By using a redundant bit of the likelihood data yₚ₁ and the posteriori probability that is obtained by the element decoder 70, the element decoder 133a repeatedly performs the error correction decoding on the likelihood data yₛ and obtains a posteriori probability. The element decoder 60 outputs the obtained posteriori probability to the element decoder 133b via the interleaver 134.

By using a redundant bit of the likelihood data yₚ₂ and the posteriori probability that is obtained by the element decoder 60, the element decoder 133b repeatedly performs the error correction decoding on the likelihood data yₛ and obtains a posteriori probability. The element decoder 133b outputs the obtained posteriori probability to the element decoder 133a via the deinterleaver 135. The posteriori probability obtained by the element decoder 133b becomes decoded information bits. In the turbo coding, the error correction performance is enhanced because the element decoders 133a and 133b repeatedly perform the error correction decoding.

The interleaver 134 is an interleaver that changes the sequence of the likelihood data yₛ. The deinterleaver 135 is an interleaver that changes the sequence of the bit string of the posteriori probability such that the sequence of data is inverted with respect the sequence changed by the interleaver 134.

The receiving device 130 performs the decoding process in ascending order of the encoding rate. For example, in FIG. 1, if the encoding rate R0 of the rate matching unit 126a is lower than the encoding rate R1 of the rate matching unit 126b, the encoding rate of the likelihood data yₚ₁ is lower than that of the likelihood data yₚ₂. In such a case, the element decoder 133a performs the decoding process first and then the element decoder 133b performs the decoding process. The information on the encoding rates R0 and R1 may also be held by the element decoders 133a and 133b.

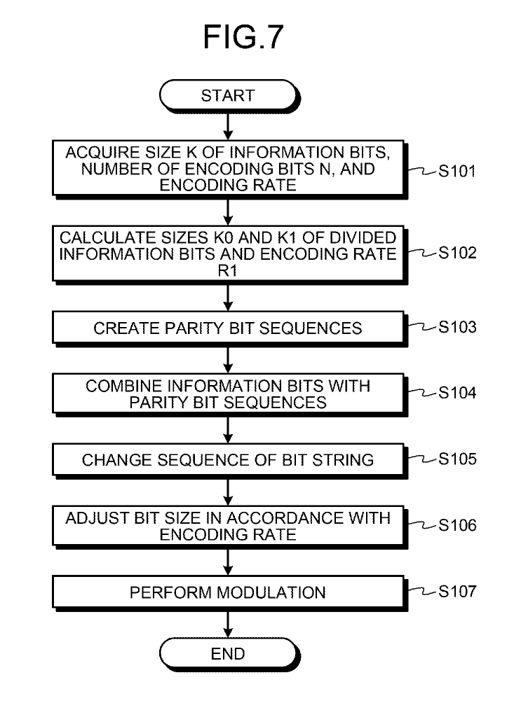

In the following, the flow of a process performed by the transmission device 120 according to the first embodiment will be described. FIG. 7 is a flowchart illustrating the flow of a process performed by the transmission device according to the first embodiment. As illustrated in FIG. 7, the control unit 120a acquires the size K of the information bits, the number of encoding bits N, and the encoding rate R0 (Step S101) and calculates the sizes K0 and K1 of divided information bits and the encoding rate R1 (Step S102).

The element encoders 122a and 122b creates the parity bit sequences 1 and 2 (Step S103). The P/S converting units 124a and 124b combines the information bits (systematic bit sequence) with the parity bit sequences (Step S104).

The channel interleavers 125a and 125b changes the sequence of the bit string (Step S105) and the rate matching unit 126a adjusts the bit size in accordance with the encoding rate (Step S106). Then, the multi level modulating unit 127 performs the modulation in accordance with the information acquired from the rate matching units 126a and 126b (Step S107).

As described above, the transmission device 120 according to the first embodiment divides the information bits, calculates the parity bit sequences 1 and 2 from the divided information bits, and combines the parity bit sequences 1 and 2 with the information bits (encoded information bits) in such a manner that the calculated parity bit sequences 1 and 2 are not added to the same information bits. Then, the transmission device 120 reorders the combined information, distributes the reordered information to each of the levels L0 and L1, and performs the multi level modulation. Accordingly, the transmission device 120 equally exerts an effect of noise occurring at the time of transmission on each bit contained in the information bits, thus making the reliability of each bit contained in the information bits constant.

In the first embodiment, a description has been given using the multi level modulation technique as an example of the modulation technique; however, the modulation technique is not limited to the multi level modulation. For example, the hierarchical modulation scheme that has been described with reference to FIG. 16 may also be used as the modulation technique.

### [b] Second Embodiment

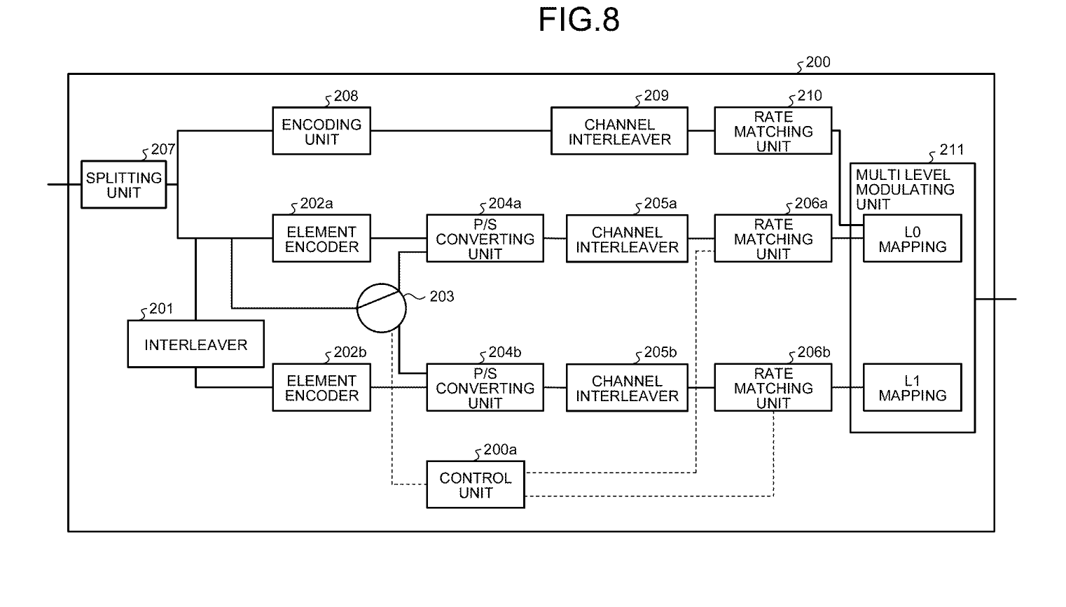

In the following, a transmission device according to a second embodiment will be described. FIG. 8 is a schematic diagram illustrating the configuration of a transmission device according to a second embodiment. As illustrated in FIG. 8, a transmission device 200 includes a control unit 200a, an interleaver 201, element encoders 202a and 202b, a distribution switch 203, P/S converting units 204a and 204b, channel interleavers 205a, 205b, and 209, rate matching units 206a, 206b, and 210, a splitting unit 207, an encoding unit 208, and a multi level modulating unit 211.

For the units described the above, descriptions of the interleaver 201, the element encoders 202a and 202b, the distribution switch 203, the P/S converting units 204a and 204b, the channel interleavers 205a and 205b, and the rate matching units 206a and 206b will be omitted here because they have the same functions as those performed by the control unit 120a, the interleaver 121, the element encoders 122a and 122b, the distribution switch 123, the P/S converting units 124a and 124b, the channel interleavers 125a and 125b, and the rate matching unit 126a illustrated in FIG. 1.

The splitting unit 207 is a processing unit that divides information bits in accordance with the ratio that is set in advance. The splitting unit 207 outputs a first divided information bits to the encoding unit 208 and outputs a second divided information bits to the interleaver 201, the element encoder 202a, and the distribution switch 203.

When acquiring the information bits, the encoding unit 208, which is a processing unit, creates a parity bit by encoding the acquired information bits. The encoding unit 208 outputs the information obtained by combining the information bits with the parity bit to the channel interleaver 209. FIG. 9 is a schematic diagram illustrating the structure of information that is output by the encoding unit 208.

When acquiring the information in which the information bits are combined with the parity bit, the channel interleaver 209, which is a processing unit, divides the acquired information into a plurality of data units and reorders the data units in accordance with a predetermined rule. The channel interleaver 209 outputs the reordered information to the rate matching unit 210.

The rate matching unit 210 is a processing unit that adjusts the size of the information acquired from the channel interleaver 125a such that the size of the information is associated with the previously set bit size. The rate matching unit 210 outputs the information, whose size is adjusted, to the multi level modulating unit 211.

The multi level modulating unit 211 transmits the information bits in accordance with the information acquired from the rate matching units 206a, 206b, and 210. The multi level modulating unit 211 combines the information acquired from the rate matching unit 206a with the information acquired from the rate matching unit 210 and sequentially extracts the 2-bit information from the combined information. Furthermore, the multi level modulating unit 211 sequentially extracts 2 bits from the information acquired from the rate matching unit 206b.

Every time the multi level modulating unit 211 extracts 4-bit information, the multi level modulating unit 211 maps a symbol associated with the extracted 4 bits and transmits the information bits. The multi level modulating unit 211 associates the 2-bit information extracted from the information, in which the information acquired from the rate matching unit 206a is combined with the information acquired from the rate matching unit 210, with a first bit and a second bit (L0) of the 4 bits constituting the symbol. Furthermore, the multi level modulating unit 127 associates the 2-bit information extracted from the information acquired from the rate matching unit 206b with a third bit and a fourth bit (L1) of the 4 bits constituting the symbol.

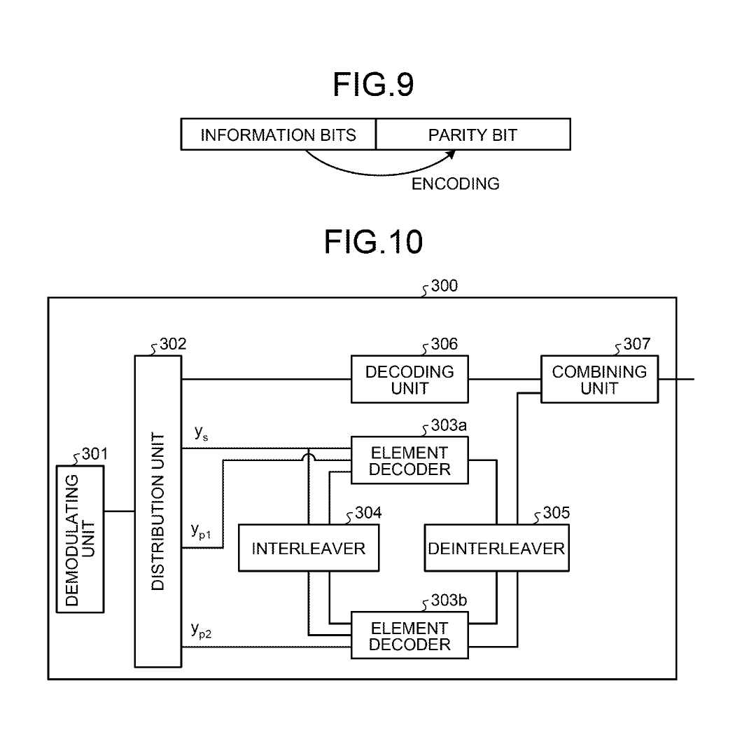

In the following, the configuration of a receiving device according to the second embodiment will be described. FIG. 10 is a schematic diagram illustrating the configuration of a receiving device 300 according to the second embodiment. As illustrated in FIG. 10, the receiving device 300 includes a demodulating unit 301, a distribution unit 302, element decoders 303a and 303b, an interleaver 304, a deinterleaver 305, an decoding unit 306, and a combining unit 307.

For the units described the above, descriptions of the demodulating unit 301, the element decoders 303a and 303b, the interleaver 304, and the deinterleaver 305 will be omitted here because they have the same functions as those performed by the demodulating unit 131, the element decoders 133a and 133b, the interleaver 134, and the deinterleaver 135 illustrated in FIG. 6.

When acquiring the information from the demodulating unit 301, the distribution unit 302 extracts, from the acquired information, the information (including noise occurring at the time of transmission) created by the encoding unit 208 and the likelihood data yₛ, yₚ₁, and yₚ₂. The distribution unit 302 outputs the information created by the encoding unit 208 to the decoding unit 306. Furthermore, the distribution unit 302 outputs the likelihood data yₛ to the element decoder 303a and the interleaver 304 and outputs the likelihood data yₚ₁ to the element decoder 303a. Furthermore, the distribution unit 302 outputs the likelihood data yₚ₂ to the element decoder 303b.

When acquiring the information from the distribution unit 302, in accordance with parity bits of the acquired information, the decoding unit 306 performs the error correction decoding on the information bits and outputs the decoded information bits to the combining unit 307.

The combining unit 307 is a processing unit that combines the information bits acquired from the deinterleaver 305 with the information bits acquired from the decoding unit 306. The information bit combined by the combining unit 307 becomes a decoded information bits.

As described above, the transmission device 200 according to the second embodiment divides the information bits; performs, on the first divided information bits, the encoding that is different from that performed in the first embodiment; and performs, on the second divided information bits, the encoding that is the same encoding performed in the first embodiment, thus making the reliability of each bit contained in the information bits constant.

The multi level modulating unit 211 according to the second embodiment maps a symbol by distributing the information acquired from each of the rate matching units 206a, 206b, and 210 using two levels L0 and L1; however, the embodiment is not limited thereto. For example, the information acquired from each of the rate matching units 206a, 206b, and 210 may also be distributed using three levels L0, L1, and L2.

For example, the multi level modulating unit 211 sequentially extracts 1-bit information from the information acquired from the rate matching unit 210 and associates the extracted 1-bit information with the first bit (L0) of the 4 bits constituting the symbol. Furthermore, the multi level modulating unit 211 sequentially extracts 1-bit information from the information acquired from the rate matching unit 206a and associates the extracted 1-bit information with the second bit (L1) of the 4 bits constituting the symbol. Furthermore, the multi level modulating unit 211 sequentially extracts the 2-bit information from the information acquired from the rate matching unit 206b and associates the extracted 2-bit information with the third bit and the fourth bit (L2) of the 4 bits constituting the symbol.

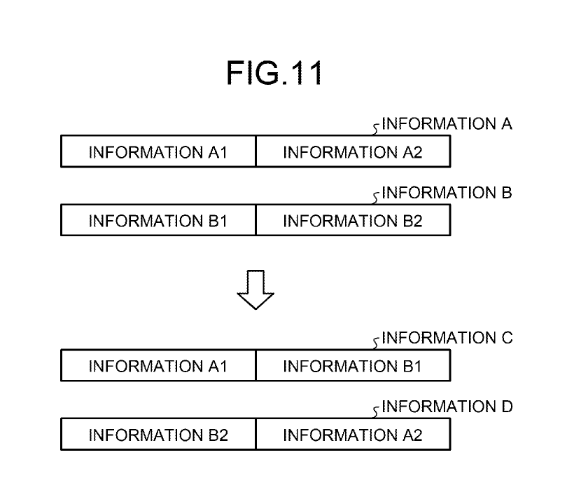

Furthermore, the multi level modulating unit 211 may also divide the information acquired from the rate matching unit 206a, divide the information acquired from the rate matching unit 206b, combine the divided information, and then modulate it. FIG. 11 is a schematic diagram illustrating another process performed by the multi level modulating unit 211.

In FIG. 11, it is assumed that information A is information acquired from the rate matching unit 206a and assumed that information B is information acquired from the rate matching unit 206b. The multi level modulating unit 211 divides the information A into information A1 and A2 and divides the information B into information B1 and B2.

Then, the multi level modulating unit 211 creates information C in which the information A1 is combined with the information B1 and creates information D in which the information B2 is combined with the information A2. The multi level modulating unit 211 sequentially extracts a total of 4 bits, i.e., extracts 2 bits from each of the information C and D; maps the symbol associated with the extracted 4 bits; and transmits the information bits.

For example, the multi level modulating unit 211 associates the 2-bit information extracted from the information C with the first bit and the second bit (L0) of the 4 bits constituting the symbol. Furthermore, the multi level modulating unit 211 associates the 2-bit information extracted from the information D with the third bit and the fourth bit (L1) of the 4 bits constituting the symbol.

Of the processes described in the embodiments, the whole or a part of the processes that are mentioned as being automatically performed can also be manually performed, or the whole or a part of the processes that are mentioned as being manually performed can also be automatically performed using known methods. Furthermore, the flow of the processes, the control procedures, the specific names, and the information containing various kinds of data or parameters indicated in the above specification and drawings can be arbitrarily changed unless otherwise noted.

The components of each unit illustrated in the drawings are only for conceptually illustrating the functions thereof and are not always physically configured as illustrated in the drawings. In other words, the specific shape of a separate or integrated device is not limited to the drawings; however, all or part of the device can be configured by functionally or physically separating or integrating any of the units depending on various loads or use conditions.

According to an aspect of the present invention, the transmission device can balance the reliability of each of the bits contained in the information bit while reducing degradation of the property.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A transmission device comprising:
a first element encoder that encodes information bits and creates a first parity bit sequence;
a second element encoder that encodes information bits in which a sequence of bit strings are changed and creates a second parity bit sequence;
a first rate matching unit that creates information obtained by combining a part of the information bits with the first parity bit sequence and adjusts a bit size of the created information;
a second rate matching unit that creates information obtained by combining a part of the information bits with the second parity bit sequence and adjusts a bit size of the created information; and
a multi level modulating unit that creates a bit string by combining the information that is output from the first rate matching unit with the information that is output from the second rate matching unit and performs multi level modulation in accordance with the bit string.

2. The transmission device according to claim 1, wherein the multi level modulating unit performs modulation in accordance with a hierarchical modulation scheme.

3. The transmission device according to claim 1, wherein
the first rate matching unit adjusts the bit size in accordance with a first encoding rate, and
the second rate matching unit adjusts the bit size in accordance with a second encoding rate that is calculated in accordance with the first encoding rate.

4. The transmission device according to claim 1, further comprising:
a splitting unit that splits the information bits;
an encoding unit that creates, from among a part of the information bits that are split by the splitting unit, a parity bit; and
a third rate matching unit that creates information obtained by combining a part of the information bits with the parity bit created by the encoding unit and adjusts a size of the created information bit, wherein
the first element encoder creates the first parity bit sequence from among a part of the information bits that are split by the splitting unit,
the second element encoder creates the second parity bit sequence from among a part of the information bits that are the same as those created by the first element encoder,
the multi level modulating unit creates a bit string by combining information that is output from the first, second, and third rate matching units and performs the multi level modulation in accordance with the bit string.

5. A receiving device comprising:
a first element decoder that repeatedly performs error correction decoding on first likelihood data in accordance with a decoding result of another element decoder, the first likelihood data associated with information bits, and a second likelihood data associated with a first parity bit sequence; and
a second element decoder that repeatedly performs the error correction decoding on the first likelihood data in accordance with a decoding result of the first element decoder, the first likelihood data associated with information bits, and a third likelihood data associated with a second parity bit sequence, wherein
the first element decoder performs error correction decoding in accordance with the decoding result of the second element decoder and
the first element decoder and the second element decoder specify an order of decoding in accordance with a first encoding rate and a second encoding rate.
